(19) United States
(12) Patent Application Publication
(10) Pub. No.: US 2026/0290464 A1
(43) Pub. Date: Sep. 24, 2026

(54) MEMORY DEVICE

(71) Applicant: Kioxia Corporation, Tokyo (JP)

(72) Inventor: Takumi FUJIMOTO, Tokyo (JP)

(73) Assignee: Kioxia Corporation, Tokyo (JP)

(21) Appl. No.: 19/286,401

(22) Filed: Jul. 31, 2025

(30) Foreign Application Priority Data
Mar. 19, 2025 (JP) 2025-045706

(51) Int. Cl. G11C 16/24; G11C 16/04; G11C 16/32; G11C 29/52

(52) U.S. Cl. CPC G11C 16/24; G11C 16/0483; G11C 16/32; G11C 29/52

(57) ABSTRACT

A first transistor has a gate coupled to a first node and is coupled to a second transistor. A latch circuit is coupled to the second transistor. A third transistor is between the first node and a second node. A fourth transistor is between the second node and a bit line. The bit line is coupled to a node of a first potential at a first time during a first period over which a first voltage is applied to the first word line. A potential of a gate of the fourth transistor is set to a second potential at a second time during the first period. The third transistor is turned on during the first period and during a second period after the first time. The potential of the gate of the fourth transistor is maintained at a third potential higher than the second potential during the second period.

### CROSS-REFERENCE TO RELATED APPLICATION

This application is based upon and claims the benefit of priority from Japanese Patent Application No. 2025-45706, filed Mar. 19, 2025, the entire contents of which are incorporated herein by reference.

### FIELD

Embodiments described herein relate generally to a memory device.

### BACKGROUND

The memory device can store data. The memory device capable of operating at a high speed can be used for various devices such as a personal computer.

### BRIEF DESCRIPTION OF DRAWINGS

FIG. 1 illustrates components and coupling of the components of a memory system that includes a memory device of a first embodiment.

FIG. 2 illustrates an example of components and coupling of the components of the memory device of the first embodiment.

FIG. 3 illustrates components and coupling of the components of a single block of the memory device of the first embodiment.

FIG. 4 illustrates an exploded view of the memory device of the first embodiment.

FIG. 5 illustrates an example of a partial cross-sectional structure of the memory device of the first embodiment.

FIG. 6 illustrates an example of a cross-sectional structure of a memory pillar of the memory device of the first embodiment along the XY plane.

FIG. 7 illustrates an example of distribution of threshold voltages of cell transistors of the memory device of the first embodiment each storing 3-bit data and the mapping of the data.

FIG. 8 is a circuit diagram of a sense amplifier circuit of the memory device according to the first embodiment.

FIG. 9 schematically illustrates potentials of several interconnects and signals during data reading of the memory device of the first embodiment along time.

FIG. 10 illustrates some components and connections of the components during data reading of the memory device of the first embodiment.

FIG. 11 schematically illustrates potentials and elements of several interconnects and signals during data reading of the memory device of the first embodiment along time.

FIG. 12 schematically illustrates potentials and elements of several interconnects and signals during data reading of a reference memory device along time.

FIG. 13 illustrates an example of threshold voltage distributions and read voltages of cell transistors storing 3-bit data in a memory device according to a second embodiment.

FIG. 14 schematically illustrates potentials of several interconnects and signals during data reading of the memory device of the second embodiment along time.

FIG. 15 schematically illustrates potentials and elements of several interconnects and signals during data reading of the memory device of the second embodiment along time.

FIG. 16 schematically illustrates potentials and elements of several interconnects and signals during data reading of a first reference memory device for comparison along time.

FIG. 17 schematically illustrates potentials and elements of several interconnects and signals during data reading of a second reference memory device for comparison along time.

### DETAILED DESCRIPTION

In general, according to one embodiment, a memory device includes a bit line, a source line, a cell transistor, a first transistor, a second transistor, a latch circuit, a third transistor, and a fourth transistor. The cell transistor is coupled between the bit line and the source line and coupled to a first word line. The first transistor has a gate coupled to a first node. The second transistor is coupled to the first transistor. The latch circuit is coupled to the second transistor. The third transistor is between the first node and a second node. The fourth transistor is between the second node and the bit line. The bit line is coupled to a node of a positive first potential at a first time during a first period over which a positive first voltage is applied to the first word line. A potential of a gate of the fourth transistor is set to a second potential at a second time during the first period. The third transistor is turned on during the first period and during a second period after the first time. The potential of the gate of the fourth transistor is maintained at a third potential higher than the second potential during the second period.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. The figures may include components which differ in relations positions and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

### 1. First Embodiment

### 1.1. Configuration (Structure)

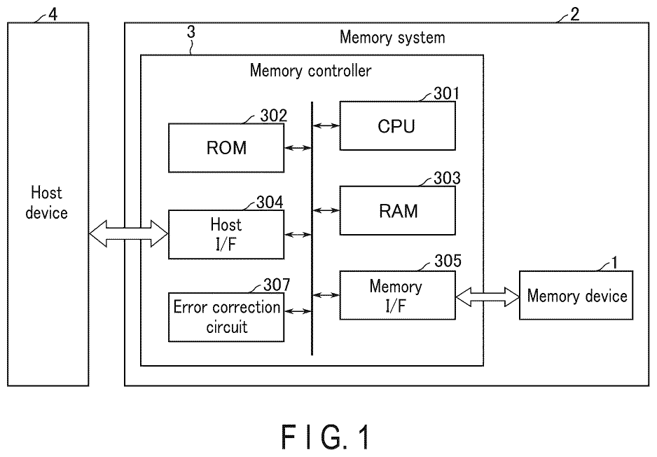

FIG. 1 illustrates an example of components and coupling of the components of a memory system that includes a memory device of a first embodiment.

As illustrated in FIG. 1, the memory system 2 includes a memory device 1 and a memory controller 3. The memory system 2 is a device that stores data. Examples of the memory system 2 include a memory card such as a SD™ card, a universal flash storage (UFS), and a solid state drive (SSD). The memory system 2 stores, reads, and erases data in response to a request from the host device 4. Examples of the host device 4 includes a personal computer and a sever in a data center.

The memory device 1 stores data using memory cells. The memory device 1 stores data to be written, and outputs data stored in the memory device 1. In one example, the memory device 1 is realized as a single chip.

The memory controller 3 is a controller that controls the memory device 1. Examples of the form of the memory controller 3 include an integrated circuit such as a system on a chip (SoC). The memory controller 3 controls the memory device 1 to perform process requested by the host device 4. Specifically, the memory controller 3 writes write data in the memory device 1 based on a write request from the host device 4. The memory controller 3 reads read data from the memory device 1 and transmits data based on the read data based on a read request from the host device 4.

The memory controller 3 includes a central processing unit (CPU) 302, a read only memory (ROM) 302, a random access memory (RAM) 303, a host interface (host I/F) 304, a memory interface (memory I/F) 305, and an error correction circuit 307.

The CPU 301 is a circuit that controls an overall operation of the memory controller 3. Through execution of programs stored in the ROM 302 and loaded onto the RAM 303 by the CPU 301, the memory controller 3 performs various operations.

The ROM 302 is a nonvolatile memory. The ROM 302 stores programs including firmware.

The RAM 303 is a volatile memory. The RAM 303 temporarily stores data, and stores programs stored in the ROM 302 while the memory system 2 is being supplied with a power supply.

The host interface 304 is an interface for the memory controller 3 to communicate with the host device 4. The host interface 304 includes hardware or a combination of hardware and software. The host interface 304 is coupled to the host device 4 via an interconnect for enabling communications according to a scheme which the memory controller 3 and the host device 4 comply with.

The memory interface 305 is an interface for the memory controller 3 to communicate with the memory device 1. The memory interface 305 includes hardware or a combination of hardware and software. The memory interface 305 is coupled to the memory device 1 via an interconnect for enabling communications according to a scheme based on a type of the memory device 1. The memory interface 305 transmits a command, address information, and write data to the memory device 1, and receives read data from the memory device 1. The memory interface 305 transmits various control signals for controlling the memory device 1 to the memory device 1.

The error correction circuit 307 performs process for detecting and correcting an error in data that will be written in the memory device 1, and performs detection and correction of an error in data read from the memory device 1. The error correction circuit 307 may be realized as an independent dedicated semiconductor chip, may be a circuit formed on a semiconductor substrate, or may be realized by the CPU 301 as a result of executing firmware. The error correction circuit 307 generates an error correction code from data (substantial write data) to be written in the memory device 1. The error correction code thus generated from the substantial write data is added to the substantial write data, based on a scheme of generation of the error correction code. The substantial write data, and the error correction code generated from the substantial write data are written in the memory device 1. The error correction circuit 307 corrects an error in the read data using the error correction code.

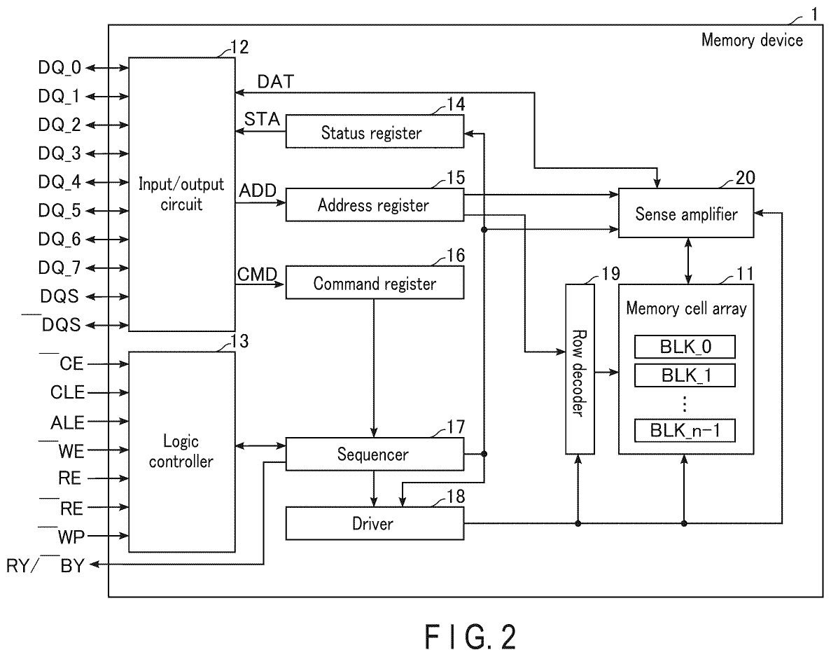

FIG. 2 illustrates an example of components and coupling of the components of the memory device of the first embodiment. As shown in FIG. 2, the memory device 1 includes components such as a memory cell array 11, an input/output circuit 12, a logic controller 13, a status register 14, an address register 15, a command register 16, a sequencer 17, a driver 18, a row decoder 19, and a sense amplifier 20.

The memory cell array 11 is a component that stores data. The memory cell array 11 includes a plurality of memory blocks (or, blocks) BLK. Each block BLK includes a plurality of memory cells (or, cell transistors) MT (not shown). The memory cell array 11 also includes interconnects such as word lines WL (not shown) and bit lines BL (not shown).

The input/output circuit 12 is a circuit that transmits and receives various signals to and from the memory controller 3. The input/output circuit 12 transmits and receives input/output signals DQ (DQ_0, DQ_1, DQ_2, DQ_3, DQ_4, DQ_5, DQ_6, and DQ_7) and signals DQS and ⁻DQS. The symbol “−” indicates inverted logic of logic of a signal of a name without the symbol “−”, and indicates that a signal has an active logic (or, is asserted) if the signal whose name includes the symbol “−” is at a low (“L”) level. The set of input/output signals DQ_0 to DQ_7 functions as signals such as a command (CMD), write data or read data (DAT), address information (ADD), and status information (STA). The signals DQS and ⁻DQS indicate timing of taking in the input/output signals DQ_0 to DQ_7.

The logic controller 13 transmits and receives signals to and from the memory controller 3. The logic controller 13 receives signals ⁻CE, CLE, ALE, ⁻WE, RE, ⁻RE, and ⁻WP. The signal ⁻CE indicates that the memory device 1 should be enabled. The signal CLE indicates transmission of the command CMD by the input/output signal DQ. The signal ALE indicates transmission of the address information ADD by the input/output signal DQ. The signal ⁻WE indicates that the input/output signal DQ should be taken in. The signal ⁻RE indicates timing of output of the input/output signal DQ.

The status register 14 is a circuit that temporarily stores the status information STA. The status information STA indicates a status or result for one or more of various items regarding the memory device 1. The status information STA is transmitted from the sequencer 17 and transmitted to the input/output circuit 12.

The address register 15 is a circuit that temporarily stores the address information ADD received by the memory device 1. In one example, the address information ADD includes a block address, a page address, and a column address. The block address, the page address, and the column address specify a block BLK, a word line WL, and a bit line BL, respectively. The address information ADD is received from the outside of the memory device 1, or, in one example, the memory controller 3, and transmitted to the address register 15.

The command register 16 temporarily stores the command CMD received by the memory device 1. The command CMD instructs the memory device 1 to perform various operations including data read, data write, and data erase.

The sequencer 17 is a circuit that controls an overall operation of the memory device 1. Based on the command CMD received from the command register 16, the sequencer 17 controls the driver 18, the row decoder 19, and sense amplifier 20 to perform various operations including data read, data write, and data erase. The sequencer 17 transmits a ready/busy signal RY/⁻BY. The ready/busy signal RY/⁻BY indicates whether the memory device 1 is in a ready state or in a busy state, and indicates the busy state by a low level. When the memory device 1 is in the ready state, the memory device 1 accepts the command CMD. When the memory device 1 is in the busy state, the memory device 1 does not accept the command CMD.

The driver 18 is a circuit that applies various voltages necessary for the operation of the memory device 1 to several components. The driver 18 receives a power supply voltage from the outside of the memory device 1, and generates a plurality of voltages from the power supply voltage. The driver 18 supplies the generated voltages to the memory cell array 11, the sense amplifier 20, and the row decoder 19.

The row decoder 19 is a circuit for selecting a block BLK. The row decoder 19 transfers the voltages supplied from the driver 18 to a single block BLK selected based on the block address received from the address register 15.

The sense amplifier 20 is a circuit that determines data stored in the memory cell array 11. The sense amplifier 20 senses a state of the cell transistor MT, generates read data based on the sensed state. The generated read data DAT is transmitted to the input/output circuit 12. The sense amplifier 20 receives the write data DAT and transfers the received write data DAT to the cell transistor MT. The sense amplifier includes a plurality of sense amplifier circuits SAC (not shown).

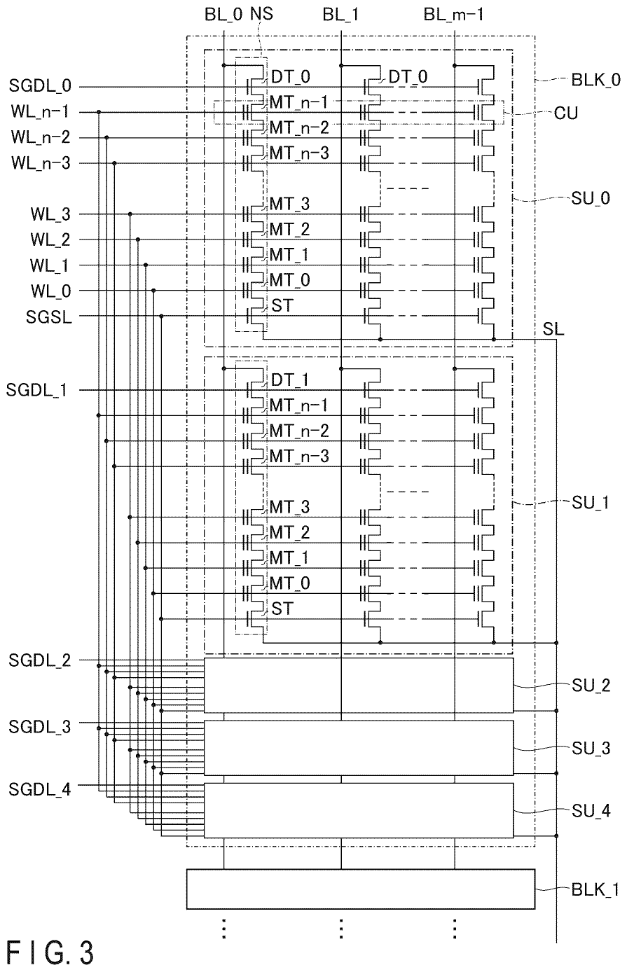

FIG. 3 illustrates components and coupling of the components of a single block of the memory device of the first embodiment. A plurality of blocks BLK, for example, all blocks BLK, include the components and the coupling illustrated in FIG. 3.

A single block BLK includes a plurality of string units SU. FIG. 3 illustrates an example of five string units SU_0 to SU_4.

As illustrated in FIG. 3, each of m-number of bit lines BL_0 to BL_m-1 is coupled, in each block BLK, to a single NAND string NS from each of string units SU_0 to SU_4., where m is a positive integer.

Each NAND string NS includes a single select gate transistor ST, n-number of cell transistors MT, and a single select gate transistor DT (DT_0, DT_1, DT_2, DT_3, or DT_4), where n is a positive integer. The cell transistor MT is an element that functions as a memory cell and stores data in a nonvolatile manner. The cell transistor MT (MT_0 to MT_n-1) includes a control gate electrode or gate electrode (or, word line WL) and a charge accumulation film insulated from the surrounding, and stores data in a nonvolatile manner based on charge in the charge accumulation film. Data is written to the cell transistor MT by injecting electrons into the charge accumulation film.

The select gate transistors ST, cell transistors MT_0 to MT_n-1, and select gate transistor DT are coupled in series in the named order between a source line SL and a single bit line BL.

A plurality of NAND strings NS respectively coupled a plurality of different bit lines BL constitute a single string unit SU. In each string unit SU, the control gate electrodes of the cell transistors MT_0 to MT_n-1 are coupled to the word lines WL_0 to WL_n-1, respectively. A set of cell transistors MT, which share a single word line WL in one string unit SU, is called “cell unit CU”.

The select gate transistors DT_0 to DT_4 belong to the string units SU_0 to SU_4, respectively. In FIG. 3, the select gate transistors DT_2, DT_3, and DT_4 are not illustrated. The gate of the select gate transistor DT_0 of each of the NAND strings NS of the string unit SU_0 is coupled to a select gate line SGDL_0. Similarly, the gates of the select gate transistors DT_1, DT_2, DT_3, and DT_4 of the respective NAND strings NS of the string units SU_1, SU_2, SU_3, and SU_4 are coupled to select gate lines SGDL_1, SGDL_2, SGDL_3, and SGDL_4.

The gate of the select gate transistor ST is coupled to a select gate line SGSL.

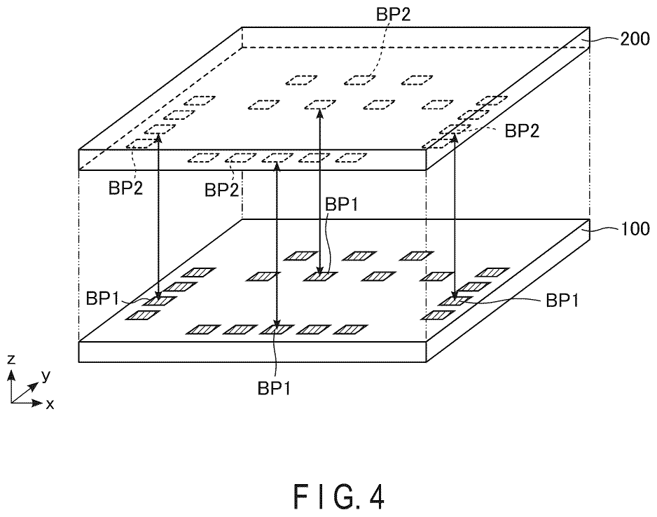

FIG. 4 illustrates an exploded view of the memory device of the first embodiment. As illustrated in FIG. 4, the memory device 1 includes a first structure 100 and a second structure 200. A plane along (or parallel to) a plane on which the first structure 100 and the second structure 200 spread is referred to as an XY plane. The XY plane includes an x axis and a y axis orthogonal to each other. The x axis extends in the X direction, and the y axis extends in the Y direction. A direction opposite to the X direction is referred to as a −X direction. A direction opposite to the Y direction is referred to as a −Y direction. A direction orthogonal to the XY plane and away from the substrate is referred to as a Z direction. A direction opposite to the Z direction is referred to as a −Z direction. The Z direction may be expressed by a direction indicated by “up” and related terms. The second structure 200 is located on an upper surface of the first structure 100.

The first structure 100 and the second structure 200 each include semiconductors, conductors, and insulators formed on a substrate using the substrate. The first structure 100 and the second structure 200 each include elements and interconnects realized by the semiconductors, conductors, and insulators. The first structure 100 and the second structure 200 each include an electric circuit including elements and interconnects. The elements and interconnects in the first structure 100 and the elements and interconnects in the second structure 200 are electrically coupled to each other.

The set of the first structure 100 and the second structure 200 includes the memory cell array 11, the input/output circuit 12, the logic controller 13, the status register 14, the address register 15, the command register 16, the sequencer 17, the driver 18, the row decoder 19, and the sense amplifier 20.

The first structure 100 includes conductive joint terminals BP1. The joint terminals BP1 are exposed on the upper surface of the first structure 100. The joint terminals BP1 are coupled to elements inside the first structure 100.

The second structure 200 includes conductive joint terminals BP2. The joint terminals BP2 are exposed on a surface of the −Z direction side (or, lower surface) of the second structure 200. The joint terminals BP2 are coupled to elements inside the second structure 200. The joint terminals BP2 have the same layout as layout of the joint terminals BP1 of the first structure 100. The joint terminals BP2 are arranged such that, in a state where the first structure 100 and the second structure 200 are joined, each joint terminal BP2 makes contact with one of the joint terminals BP1 of the first structure 100 corresponding to the joint terminal BP2. A specific joint terminal BP2 and the one of the joint terminals BP1 of the first structure 100 corresponding to the specific joint terminal BP2 are elements that function as the same node in the circuit.

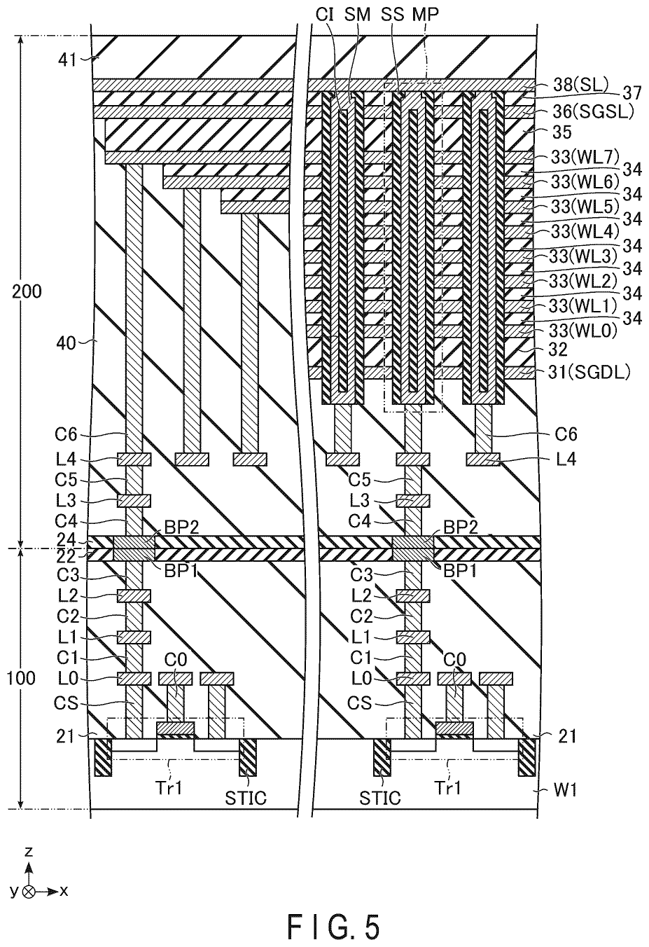

FIG. 5 illustrates an example of a partial cross-sectional structure of the memory device of the first embodiment. As illustrated in FIG. 5, the first structure 100 further includes a substrate W1, structures STIC, transistors Tr1, contacts CS, C0, C1, C2, and C3, conductors L0, L1, and L2, and insulators 21 and 22. In the following description, the conductor also includes a semiconductor which has conductivity by containing impurities. In one example, the substrate W1 includes silicon. In one example, the contacts CS, C0, C1, C2, and C3, and the conductors L0, L1, and L2 include copper or tungsten. In one example, the insulators 21 and 22 include silicon oxide.

The structure STIC has a shallow trench isolation (STI) structure. The structure STIC extends along the Z direction from an upper surface of the substrate W1 in the substrate W1. In one example, the structure STIC includes silicon oxide.

The transistor Tr1 is located in a region above and near the upper surface of the substrate W1. The transistor Tr1 includes a gate insulator on the upper surface of the substrate W1, a gate electrode on an upper surface of the gate insulator, and a pair of source/drain regions sandwiching a region below the gate electrode.

Each contact C0 is in contact, at its lower surface, with an upper surface of the gate electrode of a single transistor Tr1. Each contact CS is in contact, at its lower surface, with a single source/drain region.

Each conductor L0 is in contact, at its lower surface, with a single contact C0 or CS. Each contact C1 is in contact, at its lower surface, with an upper surface of a single conductor L0.

Each conductor L1 is in contact, at its lower surface, with an upper surface of a single contact C1. Each contact C2 is in contact, at its lower surface, with an upper surface of a single conductor L1 on the lower surface.

Each conductor L2 is in contact, at its lower surface, with an upper surface of a single contact C2. Each contact C3 is in contact, at its lower surface, with an upper surface of a single conductor L2.

A set of the transistors Tr1, the contacts CS, C0, C1, C2, and C3, and the conductors L0, L1, and L2 realizes a circuit included in the first structure 100. Therefore, the first structure 100 includes the transistors Tr1, the contacts CS, C0, C1, C2, and C3, and the conductors L0, L1, and L2, which have any shapes and arrangements to realize the circuit included in the first structure 100.

The insulator 21 ranges from a level of the upper surface of the substrate W1 to a level of an upper surface of the contact C3. The insulator 21 fills a region where the transistors Tr1, the contacts CS, C0, C1, C2, and C3, and the conductors L0, L1, and L2 are not provided.

Each joint terminal BP1 is in contact, at its lower surface, with the upper surface of a single contact C3. The insulator 22 fills a region in the layer in which the joint terminal BP1 is located where the joint terminals BP1 are not provided.

The second structure 200 further includes contacts C4, C5, and C6, conductors L3, L4, 31, 33, 36, 38, insulators 24, 32, 34, 35, 37, 40, and 41, and memory pillars MP.

Each joint terminal BP2 is located in a lowermost layer of the second structure 200. The insulator 24 fills a region in a layer in which the joint terminals BP2 are located where the joint terminals BP2 are not provided.

Each contact C4 is in contact, at its lower surface, with an upper surface of a single joint terminal BP2. Each conductor L3 is in contact, at its lower surface, with an upper surface of a single contact C4.

Each contact C5 is in contact, at its lower surface, with an upper surface of a single conductor L3. Each conductor L4 is in contact, at its lower surface, with an upper surface of a single contact C5.

The conductor 31 is located above the conductor L4. The conductor 31 has a plate shape along the xy plane. The conductor 31 functions as at least a part of a select gate line SGDL. A lower surface of the conductor 31 is exposed at an edge and has a terrace.

An insulator 32 is located on an upper surface of the conductor 31. The insulator 32 has a plate shape along the xy plane.

The conductors 33 and the insulators 34 are stacked one by one alternately on an upper surface of the insulator 32. The conductors 33 and the insulators 34 have a plate shape along the xy plane. Each conductor 33 functions as at least a part of a word line WL. FIG. 5 illustrates an example where n, that is, the number of a cell transistors MT is 8. The conductors 33 function as at least a part of the word lines WL0, WL1, WL2, WL3, WL4, WL5, WL6, and WL7 in the named order from the bottom. A lower surface of each conductor 33 is exposed at an edge and has a terrace.

The insulator 35 is located on an upper surface of the uppermost conductor 33.

The conductor 36 is located on an upper surface of the insulator 35. The conductor 36 functions as at least a part of the select gate line SGSL.

The insulator 37 is located on an upper surface of the conductor 36. The conductor 38 is located on an upper surface of the insulator 37. A lower surface of the conductor 38 is exposed at an edge and has a terrace.

The memory pillar MP extends in the Z direction and penetrates the set of the conductors 31, 33, and 36, and the insulators 32, 34, 35, and 37. The memory pillar MP includes an insulator CI, a semiconductor SM, and a layer stack SS. The semiconductor SM covers a side surface of the insulator CI. The layer stack SS covers a side surface of the semiconductor SM. The layer stack SS is open at an upper end of the memory pillar MP. Part of the semiconductor SM is located in the opening and is in contact, at its upper surface, with the conductor 38.

An upper part of the memory pillar MP may be located inside the conductor 38, the layer stack SS may be open in a portion facing the conductor 38, and part of the semiconductor SM may be located inside the opening.

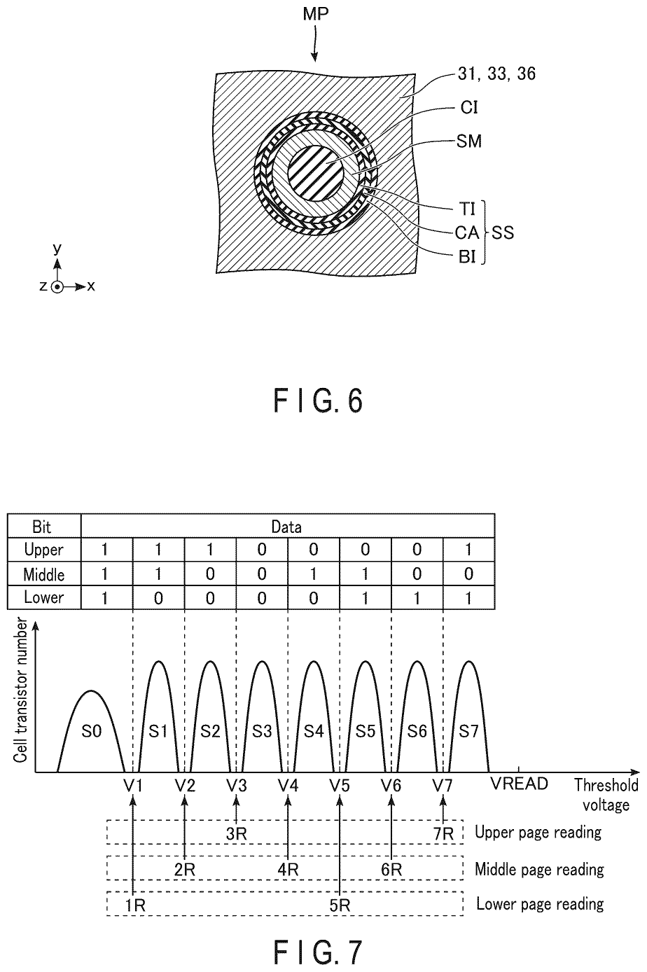

FIG. 6 illustrates an example of a cross-sectional structure of the memory pillar of the memory device of the first embodiment along the XY plane. As illustrated in FIG. 6, in one example, the layer stack SS includes a tunnel insulator TI, a charge accumulation film CA, and a block insulator BI.

The tunnel insulator TI surrounds a side surface of the semiconductor SM. The charge accumulation film CA surrounds a side surface of the tunnel insulator TI. The block insulator BI surrounds a side surface of the charge accumulation film CA. The conductor 31, 33 or 36 surrounds the side surface of the block insulator BI.

The semiconductor SM functions as a channel (or, current path) for the cell transistor MT and the select gate transistors DT and ST. In one example, each of the tunnel insulator TI and the block insulator BI includes silicon oxide. The charge accumulation film CA accumulates charge. In one example, the charge accumulation film CA includes silicon nitride.

Referring back to FIG. 5, a part of the memory pillar MP that faces the conductor 31 functions as a single select gate transistor DT. A part of the memory pillar MP that faces the conductor 33 functions as a single cell transistor MT. A part of the memory pillar MP that faces the conductor 36 functions as a single select gate transistor ST. A lower surface of the semiconductor SM is exposed on the lower surface of each memory pillar MP. A lower surface of the semiconductor SM is exposed on an upper surface of the memory pillar MP.

Each contact C6 is in contact, at its lower surface, with an upper surface of a single conductor L4. Each of some contacts C6 is in contact, at is upper surface, with a lower surface of the semiconductor SM of a single memory pillar MP. Each of some contacts C6 is in contact, at its upper surface, with a lower surface of the terrace portion of a single conductor of the conductors 31, 33, and 37 on the upper surface.

The insulator 40 ranges from a level of an upper surface of the insulator 24 to a level of an upper surface of the conductor 38. The insulator 40 fills a region of the second structure 200 where the contacts C4, C5, and C6, the conductors L3, L4, 31, 33, 36, 38, the insulators 40, 32, 34, 35, 37, and the memory pillars MP are not provided.

The insulator 41 is located on the upper surface of each of the conductor 38 and the insulator 40.

The memory device 1 can store two or more bits of data in a single cell transistor MT. FIG. 7 illustrates an example of distribution of threshold voltages of the cell transistors MT of the memory device 1 of the first embodiment each storing 3-bit data and the mapping of the data. The threshold voltage of each cell transistor MT has a magnitude corresponding to the stored data based on the amount of electrons in the charge storage film CA. In the case of 3-bit storage, each cell transistor MT is in one of “S0”, “S1”, “S2”, “S3”, “S4”, “S5”, “S6”, and “S7” sates based on the threshold voltage. The cell transistors MT in the “S0”, “S1”, “S2”, “S3”, “S4”, “S5”, “S6”, and “S7” states have higher threshold voltages in the named order. The cell transistor MT is brought to the “S0” state when the threshold voltage of the cell transistor MT is lowered through the data erase.

Through the data write, a write target cell transistor MT is maintained in the “S0” state or brought to any one of the “S1”, “S2”, “S3”, “S4”, “S5”, “S6”, and “S7” states based on the data to be written. Even a plurality of cell transistors MT that store the same 3-bit data may have different threshold voltages. A set of threshold voltages in a single state is referred to as a threshold voltage lobe.

3-bit data can be assigned to any state. In one example, each state is treated as having the following 3-bit data. Regarding “ABC” in the following description, A, B, and C indicate values of upper, middle, and lower bits, respectively.

The “S0” state: “111”

The “S1” state: “110”

The “S2” state: “100”

The “S3” state: “000”

The “S4” state: “010”

The “S5” state: “011”

The “S6” state: “001”

The “S7” state: “101”

The data read is based on determination of the state of a read target cell transistor MT. Read voltages VCGR having different magnitudes are used for the determination of the state. While the cell transistor MT is receiving the read voltage VCGR at its gate electrode, the cell transistor remains off if the cell transistor MT has a threshold voltage equal to or higher than the read voltage VCGR, and remains on if the cell transistor MT has a threshold voltage lower than the read voltage VCGR. Based on this, it is determined whether the read target cell transistor MT has a threshold voltage higher than the read voltage VCGR.

Determination whether the read target cell transistor MT is in a state higher than the “S0”, “S1”, “S2”, “S3”, “S4”, “S5”, “S6”, and “S7” states is performed using read voltages V1, V2, V3, V4, V5, V6, and V7, respectively. The read voltages V1, V2, V3, V4, V5, V6, and V7 are higher in the named order. Obtaining a set of bits indicating whether the cell transistors MT are on or off by application of the read voltages V1, V2, V3, V4, V5, V6, and V7, or data read, are referred to as 1R, 2R, 3R, 4R, 5R, 6R, and 7R, respectively.

A set of data of bits (or, bit string) at the same position (or, digit) in the cell transistors MT of a single cell unit CU constitutes a single page. A set of data of the least significant (i.e., first digit from the bottom) bits (or, bit string), or lower bits, of the cell transistors MT of each cell unit CU is referred to as a lower page. A set of data of the second least significant bits (or, bit string), or middle bits, of the cell transistors MT of each cell unit CU is referred to as a middle page. A set of data of the third least significant bits, or upper bits, of the cell transistors MT of each cell unit CU is referred to as an upper page.

Read of the lower page uses the 1R and 5R. Data of the lower page can be determined through the 1R and 5R.

Read of the middle page uses the 2R, 4R, and 6R. Data of the middle page can be determined through the 2R, 4R, and 6R.

Read of the upper page uses the 3R and 7R. Data of the upper page can be determined through the 3R and 7R.

A read pass voltage VREAD has a magnitude that turns on the cell transistor MT regardless of the data stored in the cell transistor MT.

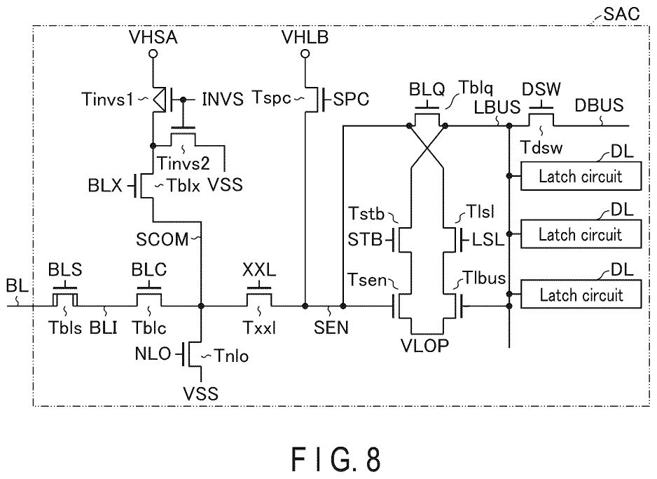

FIG. 8 is a circuit diagram of a sense amplifier circuit of the memory device according to the first embodiment. Each sense amplifier circuit SAC includes a p-type metal oxide semiconductor field effect transistor (MOSFET) Tinvs1, an n-type MOSFET Tbls, Tblc, Txxl, Tinvs2, Tblx, Tnlo, Tspc, Tblq, Tlsl, Tlbus, Tstb, Tsen, and Tdsw, and a latch circuit DL.

The transistor Tbls is coupled between one bit line BL coupled to the sense amplifier circuit SAC of FIG. 8 and the node BLI. The transistor Tbls receives a signal BLS at its gate.

The transistor Tblc is coupled between the node BLI and a node SCOM. The transistor Tblc receives a signal BLC at its gate.

The transistor Txxl is coupled between the node SCOM and a node SEN. The transistor Txxl receives a signal XXL at its gate.

The transistors Tinvs1 and Tblx are coupled in series between a node receiving a positive power supply voltage VHSA and the node SCOM in this order. The node receiving the positive power supply voltage VHSA receives the power supply voltage VHSA from the driver 18. The transistor Tinvs1 is coupled to a node INVS at its gate. The node INVS is a node in one latch circuit DL. The transistor Tblx receives a signal BLX at its gate.

The transistor Tnlo is coupled between the node SCOM and a node receiving a ground voltage VSS. The node receives the ground voltage VSS from the driver 18. The transistor Tnlo receives a signal NLO at its gate.

The transistor Tinvs2 is coupled between a node to which the transistor Tinvs1 and the transistor Tblx are coupled and the node receiving the ground voltage VSS. The transistor Tinvs2 is coupled to the node INVS at its gate. The node INVS is a node in one latch circuit DL.

The transistor Tspc is coupled in parallel between a node receiving a positive voltage VHLB and a node N2. The node receiving the positive voltage VHLB receives the voltage VHLB from the driver 18. The transistor Tspc receives a signal SPC at its gate.

The transistor Tblq is coupled between the node SEN and a bus LBUS. The transistor Tblq receives a signal BLQ at its gate.

The transistors Tlsl and Tlbus are coupled in series between the node SEN and a node VLOP in this order. The transistor Tlsl receives a signal LSL at its gate. The transistor Tlbus is coupled to the bus LBUS at its gate.

The transistors Tstb and Tsen are coupled in series between the bus LBUS and the node VLOP in this order. The transistor Tstb receives a signal STB at its gate. The transistor Tsen is coupled to the node SEN at its gate.

The transistor Tdsw is coupled between the bus LBUS and a bus DBUS. The transistor Tdsw receives a signal DSW at its gate.

The latch circuit DL is coupled to the bus LBUS.

In one example, one, a plurality, or all of the signals BLS, BLC, XXL, BLX, SPC, NLO, LSL, BLQ, and STB are supplied from a sequencer 17. Alternatively, one, a plurality, or all of the signals BLS, BLC, XXL, BLX, SPC, NLO, LSL, BLQ, and STB are based on the signal supplied from the sequencer 17.

### 1.2. Operation

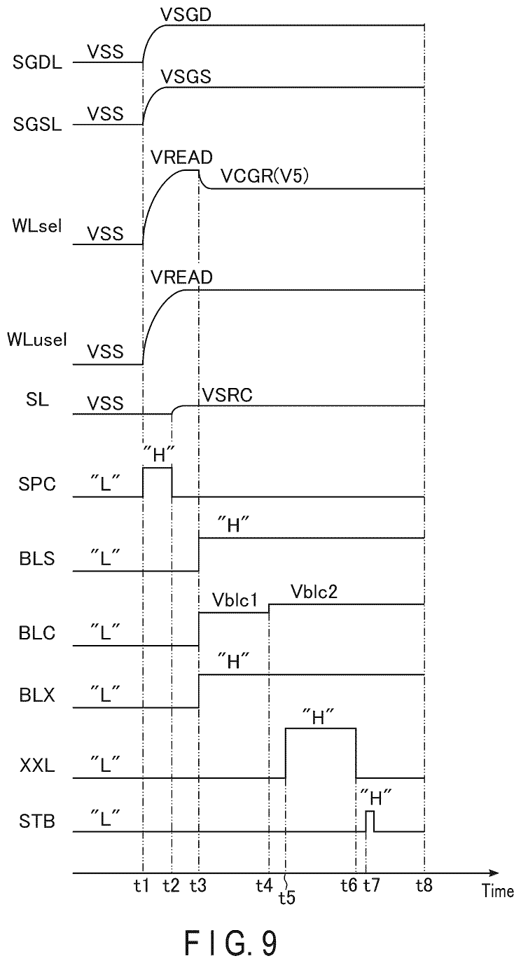

FIG. 9 schematically illustrates potentials of several interconnects and signals during data reading of the memory device of the first embodiment along time. FIG. 9 illustrates some components of the memory device 1 during reading of data from a certain cell transistor MT. Hereinafter, the cell transistor MT of the data reading target may be referred to as a selected cell transistor MTsel. A NAND string NS including the selected cell transistor MTsel may be referred to as a selected NAND string NSsel. The word line WL coupled to the selected cell transistor MTsel may be referred to as a selected word line WLsel. The word line WL other than the selected word line WLsel may be referred to as a non-selected word line WLusel.

FIG. 9 illustrates selected gate lines SGDL and SGSL in the selected NAND string NSsel. FIG. 9 illustrates a signal in the sense amplifier circuit SAC coupled to the selected NAND string NSsel via the bit line BL. FIG. 9 illustrates from the start of data reading from the selected cell transistor MTsel to the end of certain data reading, and illustrates the end of 5R as an example.

In one example, the control of the potentials illustrated in FIG. 9 is performed by the sequencer 17.

Hereinafter, a potential which a certain interconnect line has by receiving a certain voltage is denoted by the same reference numeral as that assigned to this voltage, and has substantially the same magnitude as this voltage. For example, a potential that a certain interconnect has by receiving the ground voltage VSS is referred to as a ground potential VSS, and has substantially the same magnitude as the ground voltage VSS.

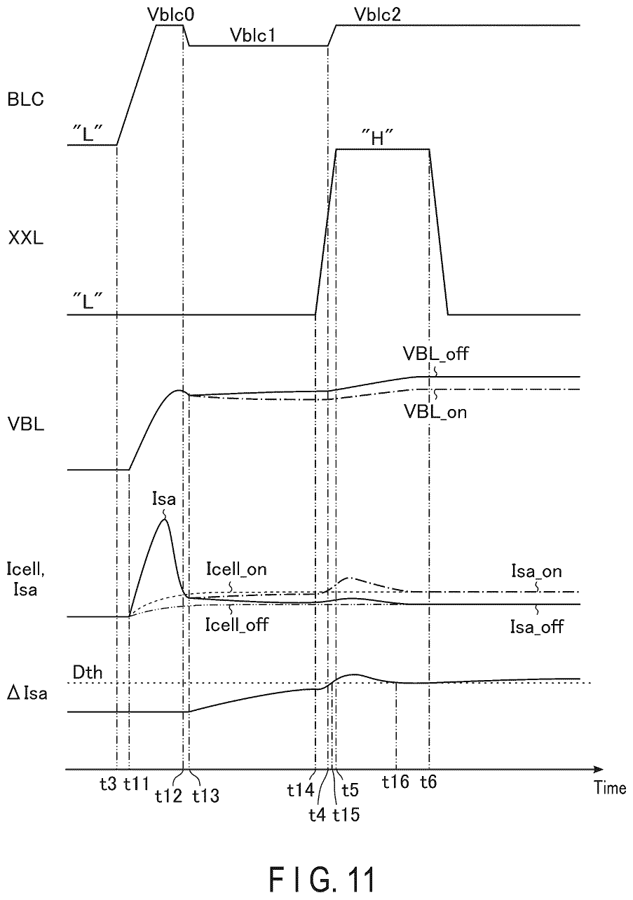

The potential of the signal BLC is schematically illustrated and detailed changes in the potential of the signal BLC will be described below with reference to FIG. 11.

At the start of the period illustrated in FIG. 9, the selected gate line SGDL, the selected gate line SGSL, the selected word line WLsel, the non-selected word line WLusel, and the source line SL have the ground potential VSS.

The signals SPC, BLS, BLC, BLX, XXL, and STB have a low level (“L”). In one example, the low level is the ground potential VSS.

At time t1, the selected gate line SGDL receives a voltage VSGD, so that the potential of the selected gate line SGDL is set to the potential VSGD. The potential VSGD has a magnitude that turns on the select gate transistor DT. A select gate transistor DT is turned on by the potential VSGD.

At time t1, the selected gate line SGDL receives a voltage VSGS, so that the potential of the selected gate line SGSL is set to the potential VSGS. The potential VSGS has a magnitude that turns on the select gate transistor ST. A select gate transistor ST is turned on by the potential VSGS.

At time t1, the selected word line WLsel and the non-selected word line WLusel receive a read pass voltage, so that the potential of the selected word line WLsel and the potential of the non-selected word line WLusel are set to the read pass potential VREAD.

At time t2, the source line SL receives a voltage VSRC, so that the potential of the source line SL is set to the potential VSRC. The potential VSRC is higher than the ground potential VSS.

At time t3, the selected word line WLsel receives a read voltage V5, so that the potential of the selected word line WLsel is set to the read potential V5. In a case where the selected cell transistor MTsel is in “S5”, “S6”, or “S7”, the selected cell transistor MTsel remains in the off state. In a case where the selected cell transistor MTsel is in “S0”, “S1”, “S2”, “S3”, or “S4”, the selected cell transistor MTsel is turned on.

At time t3, the signal SPC is temporarily set to the high level. As a result, the transistor Tspc is temporarily turned on, and during this time, the node SEN is charged via the transistor Tspc, and the potential of the node SEN increases.

At time t3, the signal BLX is set to the high level. As a result, the transistor Tblx is turned on, the node SCOM is charged via the transistor Tblx and the transistor Tinvs1 already in the on state, and the potential of the node SCOM increases.

At time t3, the potential of the signal BLC is set to a potential Vblc1, and the signal BLS is set to the high level. As a result, the transistors Tblc and Tbls are turned on, and the node SCOM is coupled to the bit line BL. Therefore, the potential of the bit line BL increases by the transfer of the potential of the node SCOM.

The changes in the potential of the selected word line WLsel and the potentials of the signals SPC, BLX, and BLC at time t3 may not be the same timing, and may be slightly different.

At time t4, the potential of the signal BLC is set to a potential Vblc2. The potential Vblc2 is higher than the potential Vblc1.

The sense operation is performed from time t5. That is, at time t5, the signal XXL is set to the high level. As a result, the transistor Txxl is turned on, and the bit line BL and the node SEN are coupled. As a result, the potential of the bit line BL is transferred to the node SEN.

At time t6, the signal XXL is set to the low level. Accordingly, the sense operation ends.

At time t7, the signal STB is temporarily set to the high level. As a result, the transistor Tsen remains in the off state or enters the on state based on the potential of the node SEN, that is, whether the selected cell transistor MTsel is in the on state or the off state. A potential based on whether the transistor Tsen is in the off state or the on state, that is, a potential based on whether the selected cell transistor MTsel is in the off state or the on state appears on the bus LBUS and is stored in any of the latch circuits DL.

After time t8, data reading using the read voltage VCGR other than the read voltage V5 is performed. The subsequent data reading is the same as the control from time t3 to time t8 except for the difference in the read voltage VCGR.

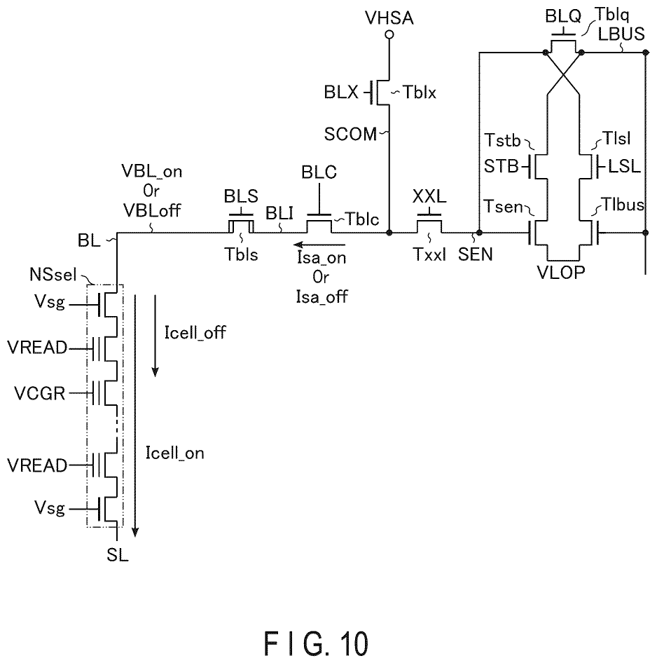

FIG. 10 illustrates some components and connections of the components during data reading of the memory device of the first embodiment. FIG. 10 illustrates a state during reading of data from the selected cell transistor MTsel.

As illustrated in FIG. 10 and described above with reference to FIG. 9, after the node SCOM is charged at time t3, the transistors Tblc and Tbls are turned on, so that a cell current Icell flows through the selected NAND string NSsel. The magnitude of the current flowing through the components shown in FIG. 10 differs based on whether the selected cell transistor MTsel is in the on state or the off state.

In a case where the selected cell transistor MTsel is in the on state, a current path is formed from the bit line BL to the source line SL. Based on this, in a case where the selected cell transistor MTsel is in the on state, an on-cell current Icell_on flows from the bit line BL to the source line SL, and an on-cell SA current Isa_on flows through the transistor Tblc. The bit line BL has an on-cell BL potential VBL_on.

In a case where the selected cell transistor MTsel is in the off state, an off-cell current Icell_off flows from the bit line BL to the selected cell transistor MTsel. Based on this, in a case where the selected cell transistor MTsel is in the off state, an off-cell SA current Isa_off flows through the transistor Tblc, and the bit line BL has an off-cell BL potential VBL_off. The off-cell SA current Isa_off is smaller than the on-cell current Icell_on. The off-cell SA current Isa_off is smaller than the on-cell SA current Isa_on. The off-cell BL potential VBL_off is higher than the on-cell BL potential VBL_on.

The sense amplifier circuit SAC uses the SA current Isa to distinguish data stored in the selected cell transistor MTsel.

The bit line BL has a parasitic capacitance between itself and an adjacent bit line BL and a parasitic capacitance between itself and a component other than the adjacent bit line BL. The parasitic capacitance with an adjacent bit line BL may be hereinafter referred to as a with-BL capacitance. The parasitic capacitance added to the bit line BL other than the with-BL capacitance may be referred to as a non-with-BL capacitance.

The BL potential VBL (VBL_on and VBL_off) depends on the potential of the node BLI, and the potential of the node BLI depends on the SA current Isa (Isa_on and Isa_off). The magnitude of the SA current Isa depends on the magnitude of the signal BLC. Using this, as described above with reference to FIG. 9, the magnitude of the signal BLC is increased from the magnitude before time t5 at time t5, thereby increasing the magnitude of the SA current Isa.

FIG. 11 schematically illustrates several interconnects and potentials and elements of signals during data reading of the memory device of the first embodiment along time. FIG. 11 shows details of the signals BLC and XXL, the BL potential VBL, the SA current Isa, and an SA current difference ΔIsa. The SA current difference ΔIsa is a difference between the magnitude of the on-cell SA current Isa_on and the magnitude of the off-cell SA current Isa_off.

As illustrated in FIG. 11, the potential of the signal BLC is set to the potential Vblc0 at time t3. The potential Vblc0 is higher than the potential Vblc1. The potential Vblc0 is used for the purpose of shortening the time for the increase of the potential Vblc to the potential Vblc1. The potential Vblc0 may not be used.

From time t11 when the potential of the signal BLC increases to some extent, the SA current Isa starts flowing. The SA current Isa charges the bit line BL, and the BL potential VBL increases. The on-cell current Icell_on or the off-cell current Icel_off flows by the increased BL potential VBL.

At time t12, the potential of the signal BLC is set to the potential Vblc1.

The magnitude of the BL potential VBL finally has a magnitude based on the magnitude of the cell current Icell. However, the non-with-BL capacitance is large, and thus a large amount of charge is required to charge the bit line BL to increase the BL potential VBL. The cell current Icell (Icell_on and Icell_off) is small until the BL potential VBL increases. For this reason, the SA current Isa is mainly spent for charging the non-with-BL capacitance until the charging of the non-with-BL capacitance ends, and the BL potential VBL is hardly affected by the on state or the off state of the selected cell transistor MTsel. Therefore, until time t13 when the charging of the non-with-BL capacitance ends, the magnitude of the BL potential VBL shows substantially the same change regardless of whether the selected cell transistor MTsel is in the on state or the off state.

Similarly, the magnitude of the SA current Isa finally has a magnitude based on the magnitude of the cell current Icell. However, the SA current Isa is mainly spent charging the non-with-BL capacitance from the beginning of the flow until charging of the non-with-BL capacitance ends. Therefore, the SA current Isa is hardly affected by the on state or the off state of the selected cell transistor MTsel. Therefore, until time t13, the magnitude of the SA current Isa shows substantially the same change regardless of whether the selected cell transistor MTsel is in the on state or the off state. Therefore, the magnitude of the SA current difference ΔIsa is zero until time t13.

At time t13, the charging of the non-with-BL capacitance ends and then the SA current Isa is mainly spent charging the with-BL capacitance. Due to that the charging of the non-with-BL capacitance ends, the SA current Isa becomes small, and the influence of the cell current Icell on the BL potential VBL relatively becomes large. Therefore, from time t13, the off-cell BL potential VBL_off becomes higher than the on-cell BL potential VBL_on based on the difference between the off-cell current Icell_off and the on-cell current Icell_on. However, since the charging of the with-BL capacitance progresses, the increase in the off-cell BL potential VBL_off is slow.

On the other hand, also in a case where the selected cell transistor MTsel is in the on state, the bit line BL is charged. However, due to the flow of the on-cell current Icell_on, the on-cell BL potential VBL_on decreases from time t13. The on-cell BL potential VBL_on has a magnitude based on the magnitude of the resistance of the current path of the selected NAND string NSsel.

As the charging of the with-BL capacitance from time t13 progresses, the proportion of the SA current Isa spent for charging the with-BL capacitance decreases. Therefore, the SA current Isa approaches the BL potential VBL, and eventually, the cell current Icell that influences the magnitude of the BL potential VBL. That is, the on-cell SA current Isa_on approaches the on-cell current Icell_on, and the off-cell SA current Isa_off approaches the off-cell current Icell_off. As described above, until the SA current Isa used for the sense amplifier circuit SAC approaches the cell current Icell reflecting the state of the selected cell transistor MTsel, it is necessary to have a time until the charging of the BL potential VBL is completed, that is, the BL potential VBL stabilizes.

The on-cell SA current Isa_on approaches the on-cell current Icell_on, and the off-cell SA current Isa_off approaches the off-cell current Icell_off, whereby the SA current difference ΔIsa increases from time t13.

As described above with reference to FIG. 9, before the signal XXL reaches the high level at time t5, the potential of the signal XXL starts to be increased from time t14.

As described above with reference to FIG. 9 and illustrated in FIG. 11, at time t4, the signal BLC is set to the potential Vblc2. As a result, the on-cell SA current Isa_on and the off-cell SA current Isa_off increase from time t4. The amount of increase in the SA current Isa depends on whether the selected cell transistor MTsel is in the on state or the off state. Since there is a difference between the off-cell BL potential VBL_off and the on-cell BL potential VBL_on, the amount of increase in the on-cell SA current Isa_on is larger than the amount of increase in the off-cell SA current Isa_off based on the Id-Vgs characteristic of the transistor Tblc. The Id-Vgs characteristic is a characteristic of the magnitude of the drain current Id with respect to the gate-source voltage of the transistor.

The on-cell BL potential VBL_on and the off-cell BL potential VBL_off are increased by acceleration of charging of the BL line BL due to an increase in the on-cell SA current Isa_on and the off-cell SA current Isa_off.

The increase of the SA current Isa is temporary, and when the BL potential VBL reaches a magnitude (a difference between the magnitude of the potential of the signal BLC and the threshold voltage of the transistor Tblc) that reaches regardless of the increase of the SA current Isa, the BL potential VBL returns to a magnitude that would be reached without the temporary increase.

Since there is a difference between the amount of increase in the on-cell SA current Isa_on and the amount of increase in the off-cell SA current Isa_off, the SA current difference ΔIsa increases. Due to the increase, the SA current difference ΔIsa exceeds a threshold Dth at time t15. The threshold Dth is the minimum magnitude of the difference between the on-cell SA current Isa_on and the off-cell SA current Isa_off requested by the sense amplifier circuit SAC to distinguish whether the selected cell transistor MTsel is in the on state or the off state. That is, in a case where the SA current difference ΔIsa exceeds the threshold Dth, the sense amplifier circuit SAC can distinguish whether the SA current Isa is a current in a case where the selected cell transistor MTsel is in the on state or a current in a case where the selected cell transistor MTsel is in the off state.

The sense operation is performed while the SA current difference ΔIsa exceeds the threshold Dth due to the temporary increase in the SA current Isa. That is, the sense operation (operation from time t5 to time t6) is performed so as to overlap with a period (from time t15 to time t16) in which the SA current difference ΔIsa exceeds the threshold Dth.

The magnitude of the potential Vblc2 and the timing of time t4 are determined based on characteristics of components involved in data reading. That is, the timings of the potential Vblc2 and the time t4 are determined such that a period in which the SA current difference ΔIsa exceeds the threshold Dth occurs due to the temporary increase in the SA current difference ΔIsa caused by the increase to the potential Vblc2. In one example, the time t4 is set to a timing at which the SA current difference ΔIsa exceeds the threshold Dth earliest based on the speed of each of the change in the potential Vblc2 and the change in the SA current Isa.

### 1.3. Advantages (Advantageous Effects)

The memory device 1 of the first embodiment can read data in a short time as described below.

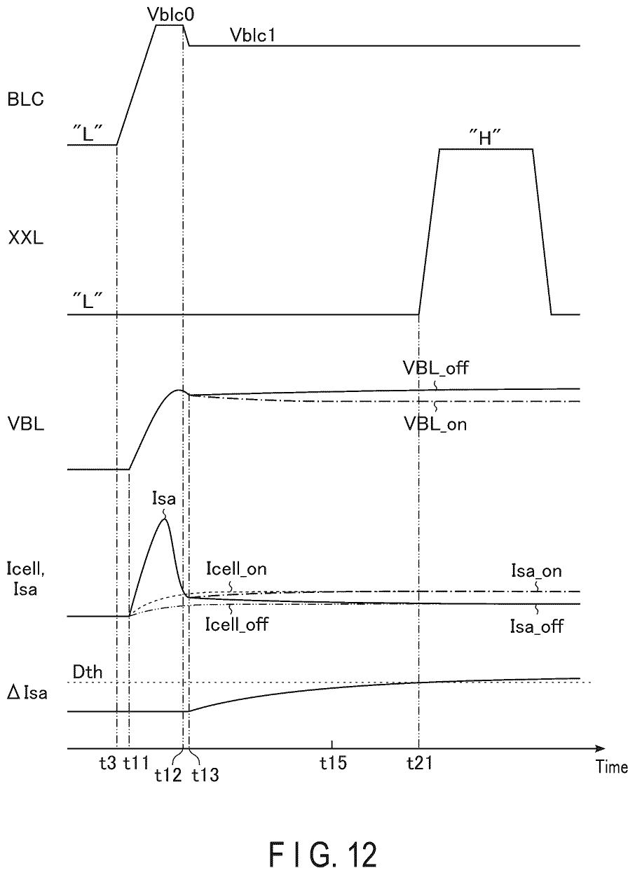

FIG. 12 shows schematically along time potentials and elements of several interconnects and signals during data reading of a memory device for reference for comparison. The memory device for reference is different from the memory device 1 in terms of control.

As illustrated in FIG. 12, the potential of the signal BLC is set to the potential Vblc1 at time t13 and then remains at the potential Vblc1. For this reason, it takes time until the BL potential VBL stabilizes, and eventually, the SA current Isa stabilizes. As a result, it takes time for the SA current difference ΔIsa to increase. Therefore, the SA current difference ΔIsa exceeds the threshold Dth at time t21, and time t21 is later than time t15. Therefore, it takes time to read data.

According to the first embodiment, as illustrated in FIG. 11, the potential of the signal BLC is set in two stages, and the sense operation is started simultaneously with or immediately after the second increase. Due to the increase in the potential of the signal BLC, the SA current difference ΔIsa temporarily increases and exceeds the threshold Dth even before the BL potential VBL stabilizes. Therefore, the time at which the SA current difference ΔIsa exceeds the threshold Dth in the memory device 1 comes before the time at which the SA current difference ΔIsa exceeds the threshold Dth in the memory device for reference. Therefore, the memory device 1 can read data in a short time.

The potential of the signal BLC only needs to be increased during the sense operation, and may be changed twice or more before the potential Vblc1 is changed to the potential Vblc2.

### 2. Second Embodiment

A memory device 1B of the second embodiment has the same components and connections of the components as those of the memory device 1 of the first embodiment. On the other hand, the memory device 1B of the second embodiment is different from the memory device 1 of the first embodiment in terms of control.

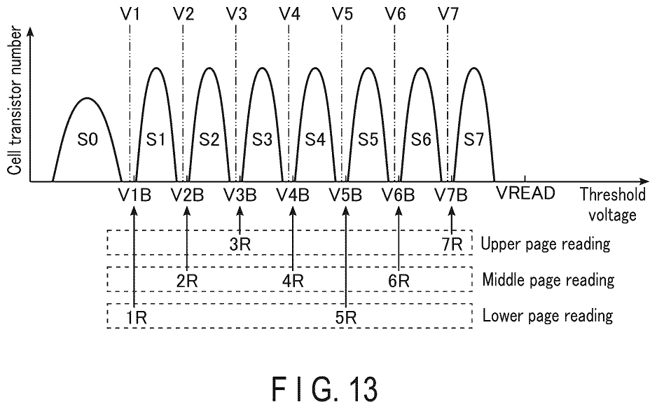

FIG. 13 illustrates an example of threshold voltage distributions and read voltages of cell transistors storing 3-bit data in the memory device according to the second embodiment. The memory device 1B uses a read voltage VCGRB. The read voltage VCGRB is any of the read voltages V1B, V2B, V3B, V4B, V5B, V6B, and V7B. The memory device 1B can use the read voltages V1B, V2B, V3B, V4B, V5B, V6B, and V7B in 1R, 2R, 3R, 4R, 5R, 6R, and 7R, respectively. In only a single or some of the 1R, 2R, 3R, 4R, 5R, 6R, and 7R, corresponding ones of the read voltages V1B, V2B, V3B, V4B, V5B, V6B, and V7B may be used. The read voltages V1B, V2B, V3B, V4B, V5B, V6B, and V7B are higher than the read voltages V1, V2, V3, V4, V5, V6, and V7, respectively.

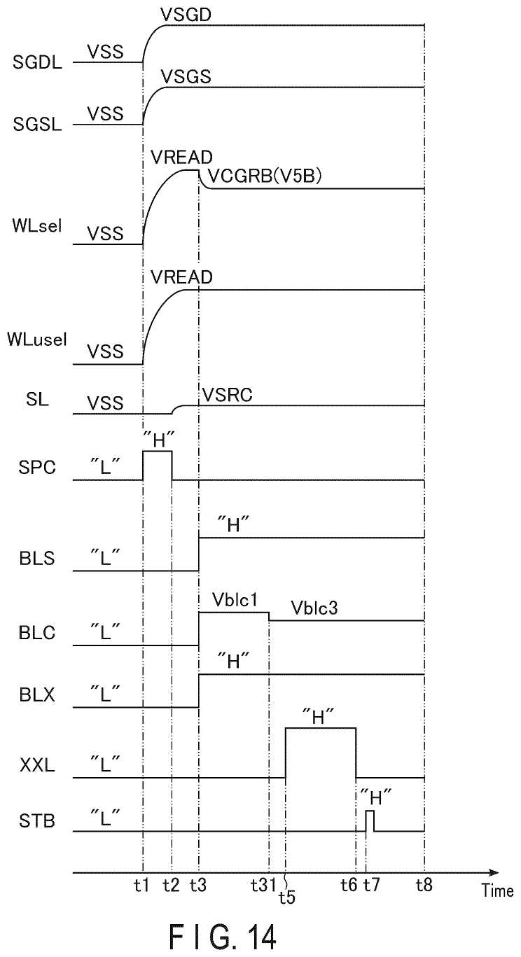

FIG. 14 schematically illustrates potentials of several interconnects and signals during data reading of the memory device of the second embodiment along time. As illustrated in FIG. 14, at time t31, the potential of the signal BLC is set to the potential Vblc3. The potential Vblc3 is lower than the potential Vblc2. The time t5 comes after the time t31.

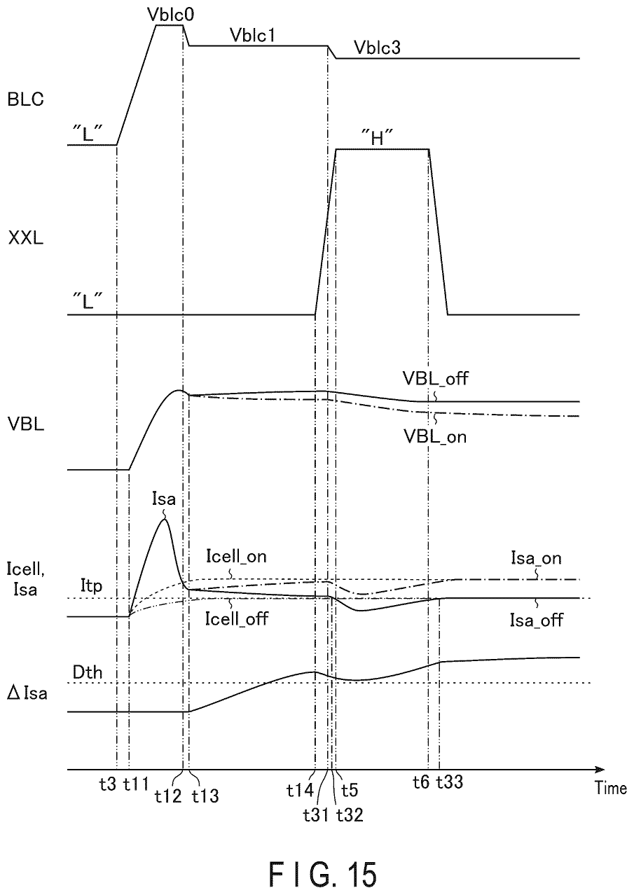

FIG. 15 schematically illustrates potentials and elements of several interconnects and signals during data reading of the memory device of the second embodiment along time. FIG. 15 shows details of the signals BLC and XXL, the BL potential VBL, the SA current Isa, and the SA current difference ΔIsa.

As described above with reference to FIG. 14 and shown in FIG. 15, at time t31, the signal BLC is set to the potential Vblc3. As a result, the on-cell SA current Isa_on and the off-cell SA current Isa_off decrease from time t31.

The on-cell BL potential VBL_on and the off-cell BL potential VBL_off decrease by the deceleration of the charging of the BL line BL due to the decrease of the on-cell SA current Isa_on and the off-cell SA current Isa_off.

The decrease of the SA current Isa is temporary, and in a case where the BL potential VBL reaches a magnitude that reaches regardless of the decrease of the SA current Isa (a difference between the magnitude of the potential of the signal BLC and the threshold voltage of the transistor Tblc), the BL potential VBL returns to a magnitude that would be reached without the temporary decrease.

By the temporary decrease of the on-cell SA current Isa_on and the off-cell SA current Isa_off, a situation in which the on-cell SA current Isa_on exceeds a trip point Itp and the off-cell SA current Isa_off falls below the trip point Itp is formed at time t32. The trip point Itp is a boundary between the on-cell SA current Isa_on and the off-cell SA current Isa_off requested by the sense amplifier circuit SAC to distinguish whether the selected cell transistor MTsel is in the on state or the off state. That is, in a case where the on-cell SA current Isa_on exceeds the trip point Itp and the off-cell SA current Isa_off falls below the trip point Itp, the sense amplifier circuit SAC can distinguish whether the SA current Isa is a current in a case where the selected cell transistor MTsel is in the on-state or a current in a case where the selected cell transistor MTsel is in the off-state. The sense operation is performed while the on-cell SA current Isa_on and the off-cell SA current Isa_off are located on both sides of the trip point Itp. That is, the sense operation (operation from time t5 to time t6) is performed so as to overlap with a period (from time t32 to time t33) in which the on-cell SA current Isa_on and the off-cell SA current Isa_off are located above and below the trip point Itp, respectively.

The magnitude of the potential Vblc3 and the timing of the time t31 are determined based on characteristics of components involved in data reading. That is, the timings of the potential Vblc3 and the time t31 are determined such that a period in which the on-cell SA current Isa_on and the off-cell SA current Isa_off are located above and below the trip point Itp occurs due to the decrease in the potential Vblc3. In one example, the time t31 is set to a timing at which a period in which the on-cell SA current Isa_on and the off-cell SA current Isa_off are located above and below the trip point Itp is formed earliest based on the speed of each of the change in the potential Vblc3 and the change in the SA current Isa.

The memory device 1B of the second embodiment can read data in a short time as described below.

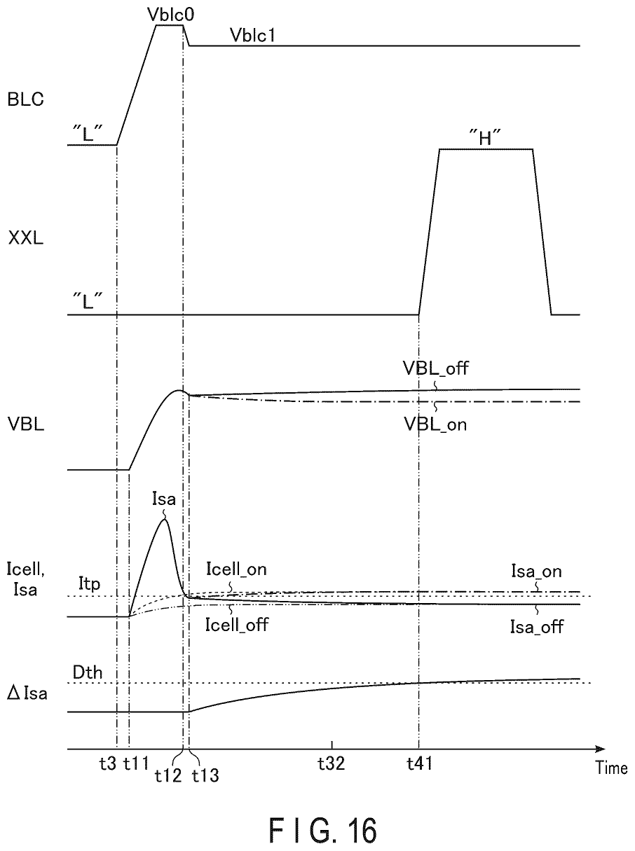

FIG. 16 schematically illustrates potentials and elements of several interconnects and signals during data reading of a first reference memory device for comparison along time. The first reference memory device is different from the memory device 1 in terms of control. The control of the first reference memory device is the same as the control of the reference memory device of the first embodiment. As described above with reference to FIG. 12, it takes time for the SA current Isa to stabilize. Therefore, as illustrated in FIG. 16, a state in which the on-cell SA current Isa_on and the off-cell SA current Isa_off are located above and below the trip point Itp, respectively, is formed at time t41. The time t41 is later than the time t32. Therefore, it takes time to read data. As a countermeasure, control in a second reference memory device can be considered.

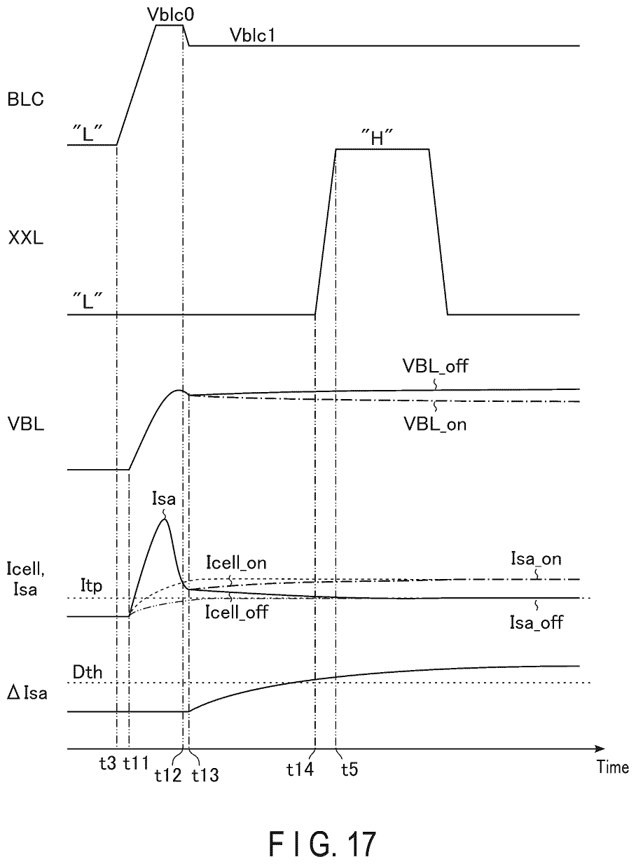

FIG. 17 schematically illustrates potentials and elements of several interconnects and signals during data reading of the second reference memory device for comparison along time. When the cell current Icell is large, the time until the BL potential VBL stabilizes is short. For that purpose, the read voltage VCGRB may be used. Due to the use of the read voltage VCGRB, the cell current Icell is large and thus the initial speed of increase is fast and thus the BL potential VBL stabilizes in a short time, as shown in FIG. 17. However, since the cell current Icell is large, the off-cell SA current Isa_off does not fall below the trip point Itp. Therefore, the sense amplifier circuit SAC cannot distinguish whether the SA current Isa is a current in a case where the selected cell transistor MTsel is in the on state or a current in a case where the selected cell transistor MTsel is in the off state.

The trip point Itp is subject to constraints caused by the layout of the components in the sense amplifier circuit SAC and/or constraints caused by conditions to be satisfied by many elements for the operation of the sense amplifier circuit SAC. Therefore, only the trip point Itp cannot be independently set to any magnitude. In addition, if a certain element is changed so that a high trip point Itp can be realized, characteristics of another element deteriorate.

As illustrated in FIG. 15, the high read voltage VCGRB is used, the potential of the signal BLC is lowered, and the sense operation is performed while the SA current Isa is lowered due to the lowering of the potential of the signal BLC. By using the high read voltage VCGRB, the stabilization of the BL potential VBL and thus the stabilization of the SA current Isa is completed in a short time, and data can be read in a short time. The decrease in the potential of the signal BLC also allows the on-cell SA current Isa_on to fall below the trip point Itp by the use of a high read voltage VCGRB. Therefore, the data stored in the selected cell transistor MTsel can be distinguished.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device, comprising:
a bit line;
a source line;
a cell transistor coupled between the bit line and the source line and coupled to a first word line;
a first transistor having a gate coupled to a first node;
a second transistor coupled to the first transistor;
a latch circuit coupled to the second transistor;
a third transistor between the first node and a second node; and
a fourth transistor between the second node and the bit line,
wherein
the bit line is coupled to a node of a positive first potential at a first time during a first period over which a positive first voltage is applied to the first word line,
a potential of a gate of the fourth transistor is set to a second potential at a second time during the first period,
the third transistor is turned on during the first period and during a second period after the first time, and
the potential of the gate of the fourth transistor is maintained at a third potential higher than the second potential during the second period.

2. The memory device according to claim 1, further comprising:
a first select transistor between the cell transistor and the bit line; and
a second select transistor between the cell transistor and the source line,
wherein
the first select transistor and the second select transistor are in an on state during the first period.

3. The memory device according to claim 2, further comprising
a fifth transistor between the second node and the node of the first potential.

4. The memory device according to claim 2, further comprising
a sixth transistor between the first node and a node of a positive fourth potential.

5. The memory device according to claim 1,
wherein the bit line is charged by a current flowing through the fourth transistor from the second time.

6. The memory device according to claim 1,
wherein the second period is a period after a difference between a potential of the bit line in a case where the cell transistor is in an on state and a potential of the bit line in a case where the cell transistor is in an off state occurs.

7. The memory device according to claim 1,
wherein the potential of the gate of the fourth transistor is set to a fifth potential higher than the second potential at the second time and then set to the second potential.

8. A memory device, comprising:
a bit line;
a source line;
a cell transistor coupled between the bit line and the source line and coupled to a first word line;
a first transistor having a gate coupled to a first node;
a second transistor coupled to the first transistor;
a latch circuit coupled to the second transistor;
a third transistor between the first node and a second node; and
a fourth transistor between the second node and the bit line,
wherein
the bit line is coupled to a node of a positive first potential at a first time during a first period over which a positive first voltage is applied to the first word line,
a potential of a gate of the fourth transistor is set to a second potential at a second time during the first period,
the third transistor is turned on during the first period, after the first time, and during a second period after a difference between a potential of the bit line in a case where the cell transistor is in an on state and a potential of the bit line in a case where the cell transistor is in an off state occurs, and
the potential of the gate of the fourth transistor is maintained at a third potential lower than the second potential during the second period.

9. The memory device according to claim 8, further comprising:
a first select transistor between the cell transistor and the bit line; and
a second select transistor between the cell transistor and the source line,
wherein
the first select transistor and the second select transistor are in an on state during the first period.

10. The memory device according to claim 9, further comprising
a fifth transistor between the second node and the node of the first potential.

11. The memory device according to claim 9, further comprising
a sixth transistor between the first node and a node of a positive fourth potential.

12. The memory device according to claim 8,
wherein the bit line is charged by a current flowing through the fourth transistor from the second time.

13. The memory device according to claim 8,
wherein the potential of the gate of the fourth transistor is set to a fifth potential higher than the second potential at the second time and then set to the second potential.
